(19) United States
(12) Patent Application Publication
(10) Pub. No.: US 2008/0286922 A1
(43) Pub. Date: Nov. 20, 2008

(54) METHOD OF FABRICATING SEMICONDUCTOR DEVICE

(75) Inventors: Haeng Leem Jeon, Seoul (KR); Ju Hyun Kim, Seoul (KR)

Correspondence Address: WORKMAN NYDEGGER, 60 EAST SOUTH TEMPLE, 1000 EAGLE GATE TOWER, SALT LAKE CITY, UT, 84111, US

(73) Assignee: DONGBU HITEK CO., LTD., Seoul (KR)

(21) Appl. No.: 12/122,296

(22) Filed: May 16, 2008

(30) Foreign Application Priority Data
May 18, 2007 (KR) 10-2007-0048561

(51) Int. Cl. H01L 21/336

(52) U.S. Cl. 438/257; 257/E21.409

(57) ABSTRACT

In one example embodiment, a method of fabricating a semiconductor device includes various steps. First, an isolation film is formed on a semiconductor substrate to define a field region and an active region. Then, a stack gate structure is formed. Next, a first photoresist and a second photoresist are sequentially formed on the stack gate structure. Then, a patterning process is performed to remove the second photoresist in a source line region. Next, a patterning process is performed to remove the first photoresist in the source line region, to thereby expose the isolation film. Then, the exposed isolation film is removed to expose the semiconductor substrate in the source line region. Finally, a cell source ion implantation process is performed using the patterned second photoresist as an ion injection mask to form a source line having impurity ions implanted thereto in the semiconductor substrate of the source line region.

### CROSS-REFERENCE TO RELATED APPLICATION

This application claims priority to Korean Application No. 10-2007-0048561, filed on May 18, 2007, which is incorporated herein by reference in its entirety.

### BACKGROUND

1. Field of the Invention

The present invention relates to a method of fabricating a semiconductor device, and more specifically, to a method of forming a common source line of a flash memory device.

2. Description of the Related Art

Generally flash memory devices have a source connection layer configured to connect sources of respective unit cells to form a source line. The source connection layer can be formed using a metal contact method which forms a contact in a source of each unit cell to connect contacts. However, this metal contact method may not be appropriate for high-integration devices. The source connection layer can also be formed using an SAS (self-aligned source) process to realize a high-integration device by using a source line made of an impurity diffusion layer.

FIGS. 1A to 1D are cross-sectional views of a flash memory semiconductor device. FIGS. 1A to 1D also disclose the formation of a source line in the flash memory semiconductor device using an RCS (Recessed Common Source) process.

Referring to FIG. 1A, an isolation film 11 is formed on a semiconductor substrate 13 to define a field region and an active region. A tunnel oxide film 15 is then formed on the semiconductor substrate 13 in the active region. In addition, a stack gate structure (made up of a floating gate 17, a dielectric film 19, and a layered control gate 21) is formed on the tunnel oxide film 15. A structure including a polysilicon layer and a metal-based material layer made of materials such as WSiₓ, W, CoSiₓ, and/or TiSiₓ has been used as the layered control gate 21 to reduce word line resistance.

Referring to FIG. 1B, as part of an SAS process, a photoresist pattern 23 having an open source line region is formed on the stack gate structure by an SAS mask work.

Referring to FIG. 1C, an SAS etch process is performed to remove the isolation layer 11 exposed in the source line region such that the semiconductor substrate 13 in the source line region is fully exposed. A hardening process is then executed after the SAS etch process is completed. During the SAS etch process and the hardening process, the photoresist pattern 23 is etched to a preset thickness, thus becoming thinner and harder.

Next, referring to FIG. 1D, a cell source ion implantation process is carried out to form a source line 25 of the flash memory device. The cell source ion implantation process uses the photoresist pattern 23 as an ion implantation mask. The cell source ion implantation process implants impurity ions into the semiconductor substrate 13 in the source line region.

It is noted that high integration of semiconductor devices has resulted in micro patterns for semiconductor devices. Unfortunately, however, photoresist scum (or photoresist residual) is produced when space between the photoresist patterns 23 is patterned. Photoresist scum may result in insufficient etching.

For example, with reference again to FIG. 1B, in case of a 130 nm flash memory device, the space A between the gates 17, 19, and 21 is about 190 nm, and the RCS space B between the photoresist patterns 23 is as about 376 nm, which is sufficient for patterning. However, in case of a 90 nm flash memory device, the space A is reduced to about 120 nm, and the RCS space B is also reduced to about 220 nm, thus producing photoresist scum during the RCS space patterning. Therefore, the photoresist scum results in insufficient etching in the SAS etch process.

FIGS. 2A and 2B are photographs showing a state where the isolation film 11 is not fully removed due to photoresist scum produced from the RCS space patterning process disclosed in FIGS. 1A to 1D. In particular, the fabrication process of 90 nm flash memory devices uses a hard mask process to cause rough topologies in the active region, which is more likely to produce photoresist scum.

One reason why the photoresist scum is produced is because photoresists in the RCS space do not easily vaporize through the relatively narrow space between the gates during the photoresist developing process. Another important reason is because lasers cannot easily penetrate into the RCS space. In other words, lasers are required to penetrate into the RCS space to cut the photoresist bonding, but since this is hindered, the photoresists in the RCS space remain are not decomposed.

### SUMMARY OF EXAMPLE EMBODIMENTS

In general, example embodiments of the invention relate to methods of fabricating a semiconductor device. The examples methods disclosed herein are able to achieve a sufficient SAS etching so that photoresist scum do not remain in the RCS space when a common source line of a flash memory device is formed.

In one example embodiment, a method of fabricating a semiconductor device includes various steps. First, an isolation film is formed on a semiconductor substrate to define a field region and an active region. Then, a stack gate structure is formed. The stack gate structure includes a floating gate and a layered control gate on the semiconductor substrate in the active region. Next, a first photoresist and a second photoresist are sequentially formed on the stack gate structure. Then, a patterning process is performed to remove the second photoresist in a source line region. Next, a patterning process is performed to remove the first photoresist in the source line region, to thereby expose the isolation film. Then, the exposed isolation film is removed to expose the semiconductor substrate in the source line region. Finally, a cell source ion implantation process is performed using the patterned second photoresist as an ion injection mask to form a source line having impurity ions implanted thereto in the semiconductor substrate of the source line region.

In another example embodiment, a method of fabricating a semiconductor device also includes various steps. First, an isolation film is formed on a semiconductor substrate to define a field region and an active region. Then, a stack gate structure is formed. The stack gate includes a floating gate and a layered control gate on the semiconductor substrate in the active region. Next, a first photoresist and a second photoresist are sequentially formed on the stack gate structure. Then, a patterning process is performed to remove the second photoresist in a source line region, while dissolving and removing the first photoresist in an open region to expose the isolation film. Next, the exposed isolation film is removed to expose the semiconductor substrate in the source line region. Finally, a cell source ion implantation process is performed using the patterned second photoresist as an ion injection mask to form a source line having impurity ions implanted thereto in the semiconductor substrate of the source line region.

### BRIEF DESCRIPTION OF THE DRAWINGS

Aspects of example embodiments of the invention will become apparent from the following description of example embodiments given in conjunction with the accompanying drawings, in which:

FIGS. 1A to 1D are cross-sectional views of a semiconductor device and disclose a prior art semiconductor device fabrication method;

FIGS. 2A and 2B are photos showing a state where an isolation film is not fully removed because of photoresist scum produced from the prior art semiconductor device fabrication method of FIGS. 1A to 1D;

FIGS. 3A to 3D are cross-sectional views of a semiconductor device and disclose a first example semiconductor device fabrication method; and

FIGS. 4A to 4C are cross-sectional views of another semiconductor device and disclosed a second example semiconductor device fabrication method.

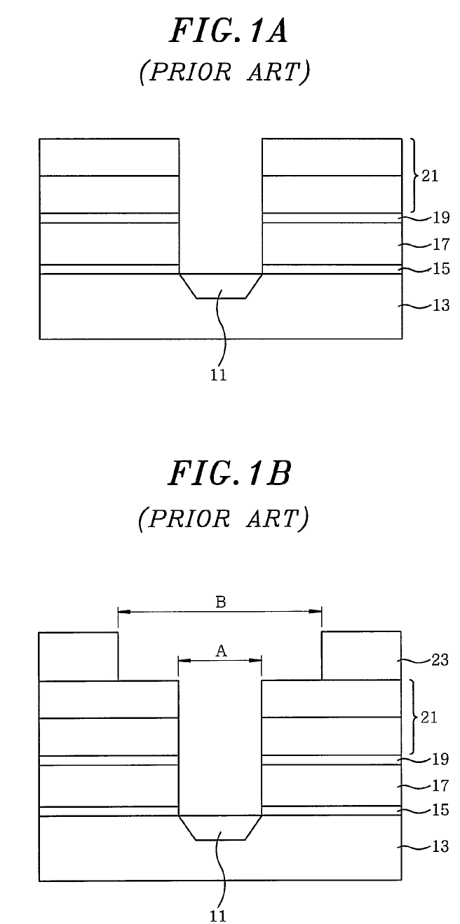

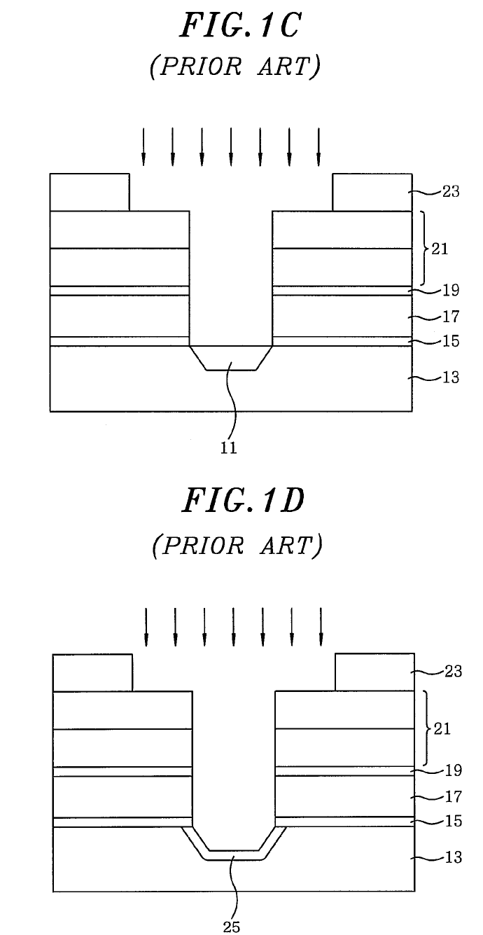

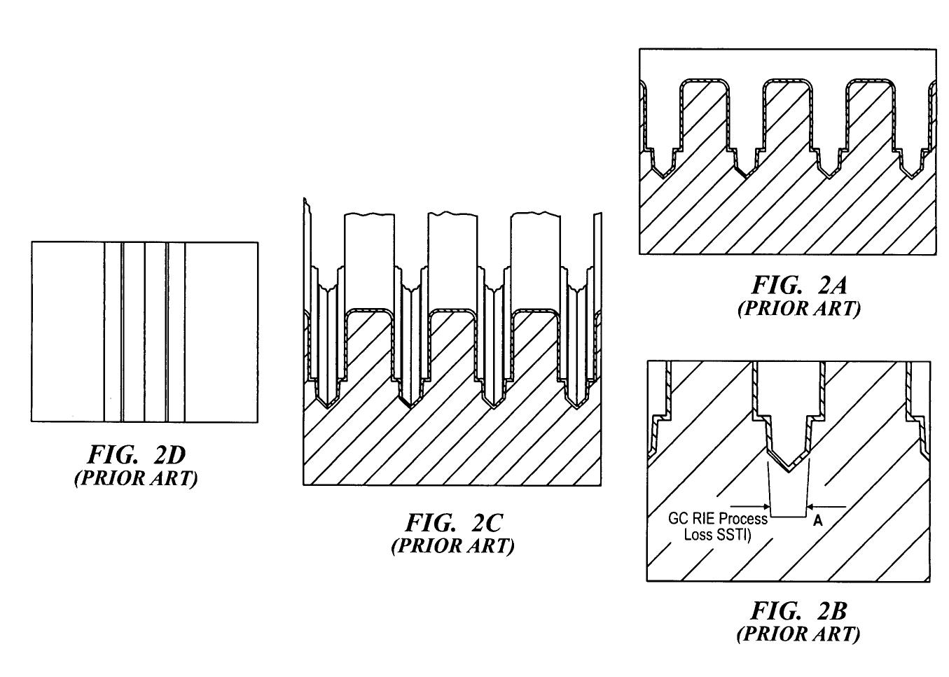

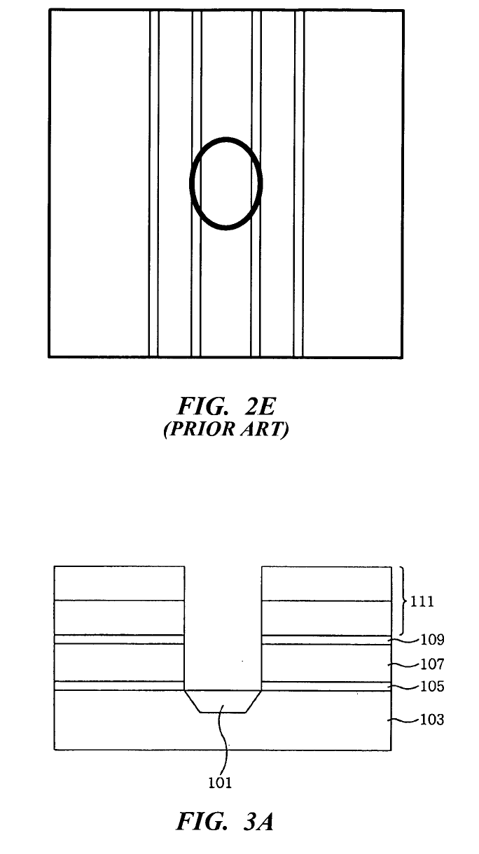

### DETAILED DESCRIPTION OF EXAMPLE EMBODIMENTS

Hereinafter, example embodiments of the invention will be described in detail with reference to the accompanying drawings.

### I. First Example Embodiment

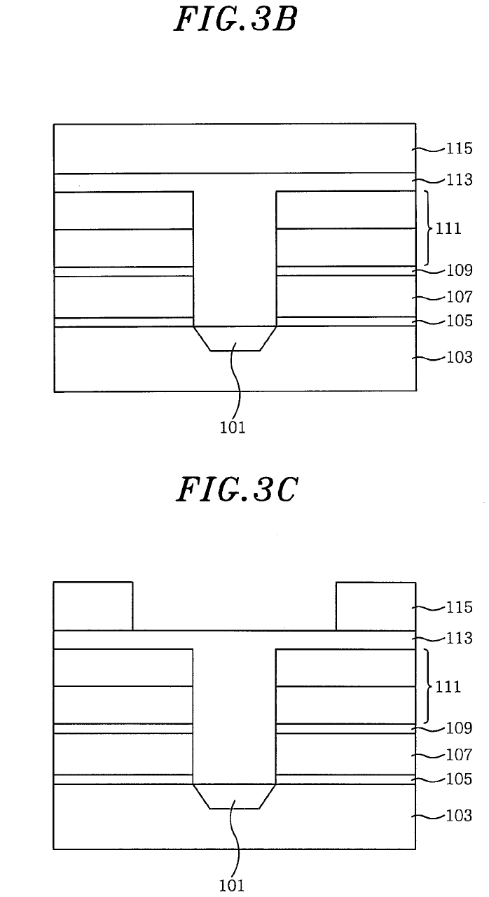

FIGS. 3A to 3D are cross-sectional views of a flash memory semiconductor device and disclose a first example semiconductor device fabrication method. The first example method is an RCS process that includes sequential steps for the formation of a source line of the flash memory semiconductor device.

Referring to FIG. 3A, an isolation film 101 is formed on a semiconductor substrate 103 to define a field region and an active region. A tunnel oxide film 105 is then formed on the semiconductor substrate 103 in the active region. In addition, a stack gate structure (made up of a floating gate 107, a dielectric film 109, and a layered control gate 111) is formed on the tunnel oxide film 105. A structure including a polysilicon layer and a metal-based material layer made of materials such as WSiₓ, W, CoSiₓ, and/or TiSiₓ can be used as the layered control gate 111 to reduce word line resistance.

Referring to FIG. 3B, an MUV (Middle Ultra Violet) positive type photoresist 113 and a DUV (Deep Ultra Violet) positive type photoresist 115 are formed sequentially on the stack gate structure. The MUV positive type photoresist 113 is exposed to MUV light used as a first light source. The DUV positive type photoresist 115 is exposed to DUV light used as a second light source. As disclosed in FIG. 3B, the MUV positive type photoresist 113 is formed higher than the top surface of the control gate 111.

Referring to FIG. 3C, the photoresist 115 in the source line region is removed by a patterning process using a DUV light. Since the patterning process uses DUV light, the photoresist 113 is not patterned.

Referring to FIG. 3D, the photoresist 113 in the source line region is removed by a patterning process using MUV light. The photoresist 115 patterned by the DUV light is then masked to remove residual photoresists in the RCS space. Compared with the DUV process, the MUV process can more easily remove the residual photoresists between narrow gates because exposure is accomplished not only at a relatively deep depth but also at relatively high energy.

Following the above processes, an SAS etch process is performed to remove the isolation film 101 exposed in the source line, so that the semiconductor substrate 103 in the source line region is fully exposed, and a hardening process is carried out after the SAS etch is completed.

Next, a cell source ion implantation process using the photoresist 115 as an ion implantation mask is performed to form a source line (not shown) of a flash memory device to which impurity ions are implanted on the semiconductor substrate 103 in the source line region.

### II. Second Example Embodiment

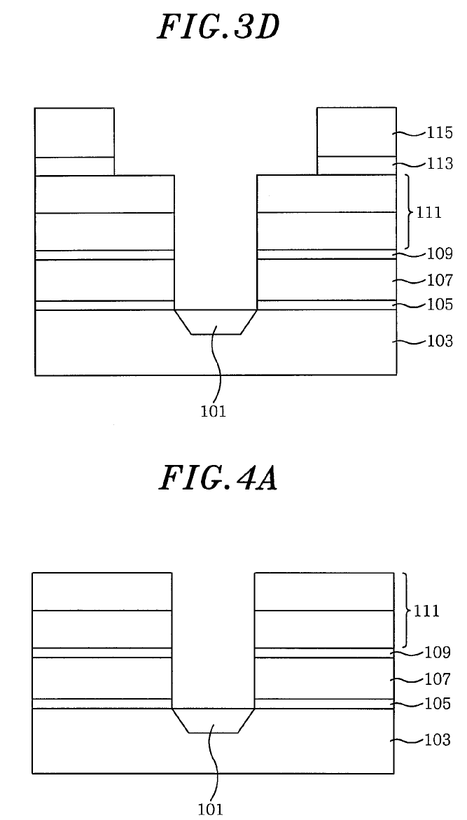

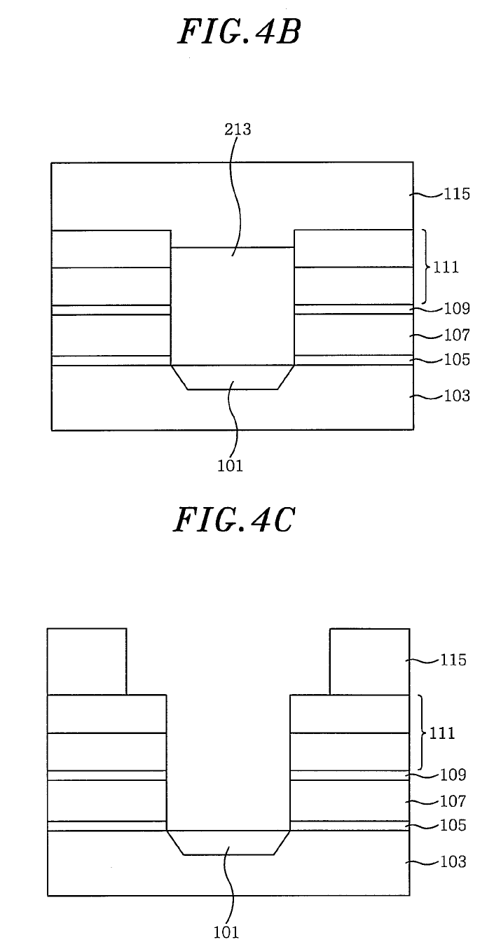

FIGS. 4A to 4C are cross-sectional views of another flash memory semiconductor device and disclose a second example semiconductor device fabrication method. The second example method includes sequential steps for the formation of a source line of the flash memory semiconductor device.

Referring to FIG. 4A, an isolation film 101 is formed on a semiconductor substrate 103 to define a field region and an active region. A tunnel oxide film 105 is then formed on the semiconductor substrate 103 in the active region. In addition, a stack gate structure (made up of a floating gate 107, a dielectric film 109, and a layered control gate 111) formed on the tunnel oxide film 105. A structure including a polysilicon layer and a metal-based material layer made of materials such as WSiₓ, W, CoSiₓ, and/or TiSiₓ can be used as the layered control gate 111 to reduce word line resistance.

Referring to FIG. 4B, an MUV negative type photoresist 213 and a DUV positive type photoresist 115 are formed sequentially on the stack gate structure. The MUV negative type photoresist 213 is not developed only when it reacts to MUV light used as a first light source. The DUV positive type photoresist 115 is exposed to DUV light used as a second light source. As disclosed in FIG. 4B, the MUV negative type photoresist 213 is formed lower than the top surface of the control gate 111.

Referring to FIG. 4C, the photoresist 115 in the source line region is removed by a patterning process using a DUV light. The photoresist 115 in the RCS space reacts to DUV light and is patterned, while the photoresist 213 in a region which is opened by patterning of the photoresist 115 is dissolved without reacting to DUV light and then removed, because it is not developed only when reacting to MUV light.

Following the above processes, an SAS etch process is performed to remove the isolation film 101 exposed in the source line, so that the semiconductor substrate 103 in the source line region is fully exposed, and a hardening process is carried out after the SAS etch is completed.

Next, a cell source ion implantation process using the photoresist 115 as an ion implantation mask is performed to form a source line (not shown) of a flash memory device to which impurity ions are implanted on the semiconductor substrate 103 in the source line region.

As explained above, when forming a common source line of a flash memory device, example embodiments disclosed herein stack plural photoresists having different developing properties under light sources in an RCS space, and then perform a patterning process utilizing those different developing properties of the photoresists, thereby reducing or eliminating photoresist scum in the RCS space to adequately complete a subsequent SAS etch process.

While example embodiments of the invention have been disclosed herein, various changes and modifications may be made without departing from the scope of the invention as defined in the following claims.

What is claimed is:

1. A method of fabricating a semiconductor device, the method comprising the steps of:
forming an isolation film on a semiconductor substrate to define a field region and an active region;
forming a stack gate structure having a floating gate and a layered control gate on the semiconductor substrate in the active region;
forming a first photoresist and a second photoresist sequentially on the stack gate structure;
performing a patterning process to remove the second photoresist in a source line region;
performing a patterning process to remove the first photoresist in the source line region, to thereby expose the isolation film;
removing the exposed isolation film to expose the semiconductor substrate in the source line region; and
performing a cell source ion implantation process using the patterned second photoresist as an ion injection mask to form a source line having impurity ions implanted thereto in the semiconductor substrate of the source line region.

2. The method of claim 1, wherein the first photoresist and the second photoresist are exposed by different light sources, respectively.

3. The method of claim 2, wherein the first photoresist includes an MUV (Middle Ultra Violet) positive type photoresist.

4. The method of claim 2, wherein the second photoresist includes a DUV (Deep Ultra Violet) positive type photoresist.

5. The method of claim 1, wherein the first photoresist is formed higher than the control gate.

6. A method of fabricating a semiconductor device, the method comprising the steps of:
forming an isolation film on a semiconductor substrate to define a field region and an active region;
forming a stack gate structure having a floating gate and a layered control gate on the semiconductor substrate in the active region;
forming a first photoresist and a second photoresist sequentially on the stack gate structure;
performing a patterning process to remove the second photoresist in a source line region, while dissolving and removing the first photoresist in an open region to expose the isolation film;
removing the exposed isolation film to expose the semiconductor substrate in the source line region; and
performing a cell source ion implantation process using the patterned second photoresist as an ion injection mask to form a source line having impurity ions implanted thereto in the semiconductor substrate of the source line region.

7. The method of claim 6, wherein the first photoresist and the second photoresist are exposed by different light sources, respectively.

8. The method of claim 7, wherein the first photoresist includes an MUV (Middle Ultra Violet) negative type photoresist.

9. The method of claim 7, wherein the second photoresist includes a DUV (Deep Ultra Violet) positive type photoresist.

10. The method of claim 6, wherein the first photoresist is formed lower than the control gate.
